(19) United States
(12) Patent Application Publication
(10) Pub. No.: US 2017/0069577 A1
(43) Pub. Date: Mar. 9, 2017

(54) SEMICONDUCTOR DEVICE, INSPECTION PATTERN ARRANGEMENT METHOD AND METHOD OF MANUFACTURING SEMICONDUCTOR DEVICE

(71) Applicant: Kabushiki Kaisha Toshiba, Tokyo (JP)

(72) Inventor: Hiroyuki Yamaguchi, Yokohama Kanagawa (JP)

(21) Appl. No.: 15/060,689

(22) Filed: Mar. 4, 2016

(30) Foreign Application Priority Data
Sep. 9, 2015 (JP) 2015-177671

(51) Int. Cl. H01L 23/544; G06F 17/50; H01L 23/535

(52) U.S. Cl. CPC H01L 23/544; H01L 23/535; G06F 17/5068; H01L 2223/54426; H01L 2223/54453

(57) ABSTRACT

According to one embodiment, there is provided a semiconductor device. The semiconductor device includes a first inspection pattern and an upper layer side pattern. The first inspection pattern is a pattern arranged in a chip region of a semiconductor chip. The upper layer side pattern is a pattern arranged on a side of a layer higher than the first inspection pattern. The upper layer side pattern overlaps at least a part of the first inspection pattern.

### CROSS-REFERENCE TO RELATED APPLICATIONS

This application is based upon and claims the benefit of priority from Japanese Patent Application No. 2015-177671, filed on Sep. 9, 2015; the entire contents of which are incorporated herein by reference.

### FIELD

Embodiments described herein relate generally to a semiconductor device, an inspection pattern arrangement method, and a method of manufacturing a semiconductor device.

### BACKGROUND

When a semiconductor device is manufactured, an alignment between an upper layer side pattern and a lower layer side pattern is performed. At this time, a mask alignment mark at the upper layer side is aligned with a mask alignment mark at the lower layer side. In the past, the mask alignment marks are arranged on a scribe line of a substrate.

However, if the mask alignment mark is formed on the scribe line, when the substrate is diced, there are cases in which dust or chipping occurs. In addition, when the mask alignment mark is arranged in a chip, there are cases in which a chip area size is increased. For this reason, it is desirable to provide a semiconductor device in which an increase in a chip area size is suppressed.

### BRIEF DESCRIPTION OF THE DRAWINGS

FIG. 1 is a top view schematically illustrating a configuration of a semiconductor chip according to an embodiment;

FIG. 2 is a top view schematically illustrating a configuration of a primitive cell region;

FIGS. 3A and 3B are diagrams illustrating arrangement examples of marks in a shot;

FIG. 4 is a diagram illustrating an arrangement example of a mark and an interconnection of an underlying group;

FIG. 5 is a diagram illustrating an arrangement example of a mark and an interconnection of an overlaying group;

FIGS. 6A and 6B are diagrams for describing a process of arranging a mark after a primitive cell is arranged;

FIG. 7 is a top view schematically illustrating a configuration of a semiconductor chip when an aspect ratio of a primitive cell region is high;

FIGS. 8A and 8B are diagrams for describing a mark arrangement process when an aspect ratio of a primitive cell region is high;

FIG. 9 is a diagram for describing a first example of a mark arrangement process;

FIG. 10 is a diagram (1) for describing a second example of a mark arrangement process; and

FIG. 11 is a diagram (2) for describing a second example of a mark arrangement process.

### DETAILED DESCRIPTION

According to one embodiment, there is provided a semiconductor device. The semiconductor device includes a first inspection pattern and an upper layer side pattern. The first inspection pattern is a pattern arranged in a chip region of a semiconductor chip. The upper layer side pattern is a pattern arranged on a side of a layer higher than the first inspection pattern. The upper layer side pattern overlaps at least a part of the first inspection pattern.

Exemplary embodiments of a semiconductor device, an inspection pattern arrangement method, and a method of manufacturing a semiconductor device will be explained below in detail with reference to the accompanying drawings. The present invention is not limited to the following embodiments.

### Embodiment

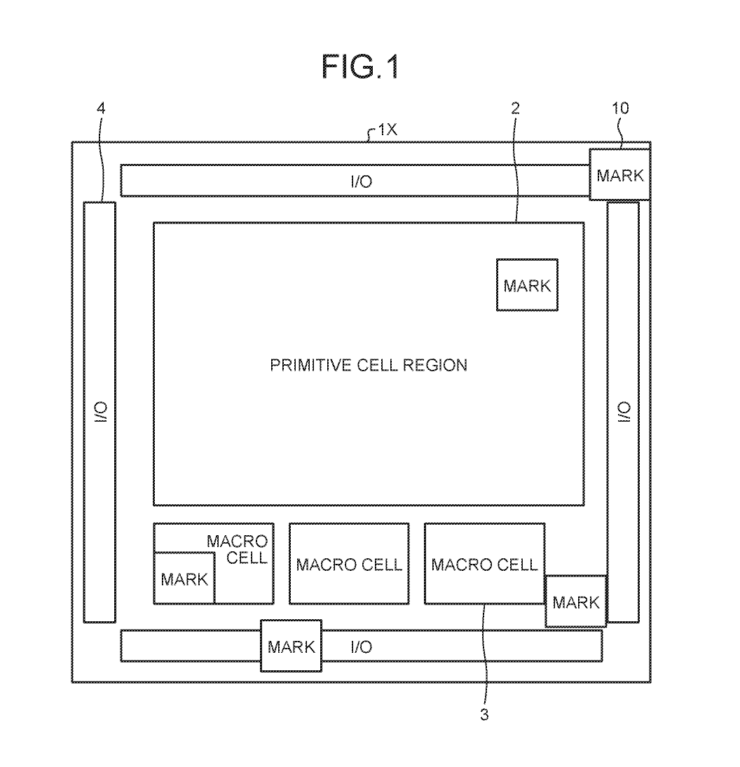

FIG. 1 is a top view schematically illustrating a configuration of a semiconductor chip according to an embodiment. A semiconductor chip (semiconductor device) 1X is formed such that various patterns are formed on a substrate such as a wafer. The semiconductor chip 1X is manufactured by forming patterns on the wafer and dicing the wafer in which the patterns are formed. In the present embodiment, a semiconductor device being manufactured and a manufactured semiconductor device are referred to collectively as a “semiconductor chip 1X.” In the present embodiment, a non-diced semiconductor device and a diced semiconductor device are referred to collectively as a “semiconductor chip 1X.”

The semiconductor chip 1X includes the primitive cell region 2, a macro cell 3, and an input/output (I/O) region 4. The primitive cell region 2 is a region in which a logic circuit is arranged. A plurality of primitive cells (standard cells) are arranged in the primitive cell region 2. The primitive cell is a functional block such as a two-input NAND circuit or a flip flop. The primitive cell region 2 is one of primitive cell regions 2A and 2B which will be described later.

The macro cell 3 is a region in which a read only memory (ROM), a random access memory (RAM), an analogue circuit, or the like is arranged. An I/O region 4 is a region in which a bonding PAD and the like are arranged.

A mark 10 serving as an example of an inspection pattern is arranged in the semiconductor chip 1X of the present embodiment. The mark (mask alignment mark) 10 is a mark pattern used for an alignment between an upper layer side pattern and a lower layer side pattern. The upper layer side pattern is a pattern formed on a layer at a mask side that is aligned. The lower layer side pattern is a pattern (a pattern formed on a layer at a wafer side) already formed on the semiconductor chip 1X. The lower layer side pattern is not limited to a pattern formed on a layer directly below a layer in which the upper layer side pattern is formed, and a plurality of layers may be formed between the upper layer side pattern and the lower layer side pattern.

When the semiconductor chip 1X is formed, a plurality of layers are stacked on a wafer. Each layer is formed by a process of performing light exposure on the wafer. When patterns of N (N is a natural number) layers are formed on the wafer, an alignment is performed using the mark 10 on the wafer formed at a lower layer side than an N-th layer and the mark 10 of the mask used in the N-th layer. Further, when the pattern of the N-th layer is formed, the mark 10 of the N-th layer is formed on the wafer at the same time as a circuit pattern of the N-th layer or the like. In other words, the circuit pattern of the N-th layer and the mark 10 of the N-th layer are formed on the N-th layer on the wafer. An inspection pattern other than the mark 10 may be arranged in the semiconductor chip 1X. The inspection pattern other than the mark 10 is, for example, a test element group (TEG) or the like.

The mark 10 may be arranged any region in the semiconductor chip 1X such as the primitive cell region 2, the I/O region 4, a corner region or an interconnection region of the semiconductor chip 1X, or the macro cell 3. The mark 10 is arranged at a position on the same layer as the mark 10 at which the circuit pattern and the like are not arranged or a position at the lower layer side at which other patterns are not arranged. In other words, the mark 10 is arranged not to overlap a pattern formed on a layer that is the same level as or lower than the mark 10 when the mark 10 is viewed from the top.

The primitive cell region 2 includes a region in which primitive cells are arranged and a region in which no primitive cell is arranged. The mark 10 is arranged not to overlap the primitive cells in the primitive cell region 2. In other words, for example, the mark 10 is arranged in a region (gap) in which no primitive cell is arranged in the primitive cell region 2. For example, the mark 10 is arranged in a region between PADs in the I/O region 4. Any pattern may be arranged on a side of a layer above the mark 10. Further, when a side lower than the mark 10 is a layer (for example, a layer formed by an implantation) having no remaining shape, the mark 10 may be arranged to overlap the layer having no remaining shape. The mark 10 is any one of marks 11A to 11D, 12A to 12D which will be described later.

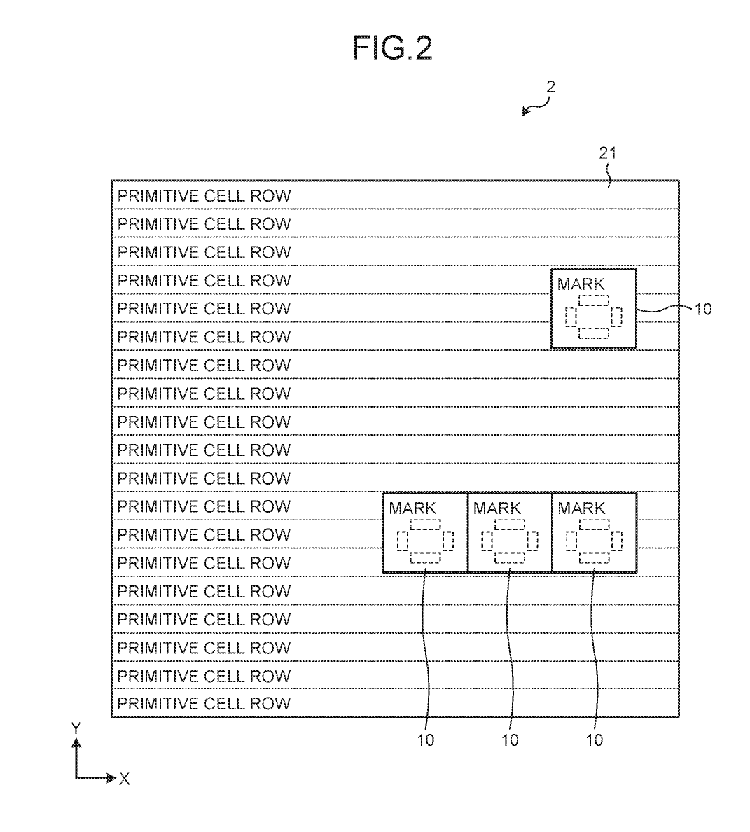

FIG. 2 is a top view schematically illustrating a configuration of the primitive cell region. A plurality of primitive cell rows 21 are arranged in the primitive cell region 2. Here, a region in which the primitive cells are arranged in a traverse direction is illustrated as the primitive cell row 21.

The primitive cell region 2 includes a region in which the primitive cell row 21 is not arranged. The mark 10 is arranged, for example in a gap region of the primitive cell region 2 in which the primitive cell row 21 is not arranged.

When the mark 10 is arranged, an automatic place and route (P&R) device sets a region in which the mark 10 is arranged (automatically placed and routed) to chip data in advance. Then, the automatic FIR device arranges a circuit pattern, a dummy pattern, and the like. Thereafter, the automatic P&R device arranges the mark 10 in the region in which the mark 10 is arranged. The region in which the mark 10 is arranged may be manually set. The mark 10 may be manually arranged. The mark 10 may be arranged one by one, or a plurality of marks 10 may be collectively arranged in units of groups.

The mark 10 includes, for example, a plurality of line patterns extending in a first direction and a plurality of line patterns extending in a second direction. FIG. 2 illustrates an example in which the mark 10 includes two line patterns extending in an X direction and two line patterns extending in a Y direction.

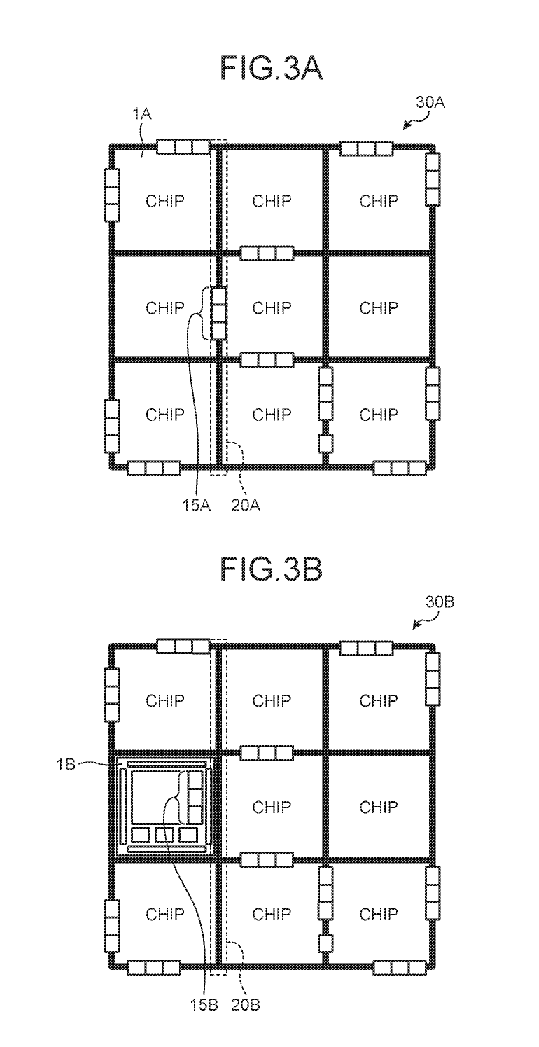

FIGS. 3A and 3B are diagrams illustrating arrangement examples of marks in a shot. The shot refers to a mask image corresponding to single light exposure when a wafer is exposed to light. A plurality of semiconductor chips are arranged in each of shots 30A and 30B. A scribe line (a scribe region) is arranged between the semiconductor chips.

Here, an example in which nine semiconductor chips 1A are arranged in the shot 30A, and nine semiconductor chips 1B are arranged in the shot 30B is illustrated. The shot 30A is a shot in which a mark group 15A is arranged on a scribe line 20A. The shot 30B is a shot in which a mark group 15B is not arranged on a scribe line 20B. Each of the mark groups 15A and 15B includes one or more marks 10.

The marks 10 configuring the mark group 15A are formed on various layers. Similarly, the marks 10 configuring the mark group 15B are formed on various layers. For example, the mark group 15B may include first to M-th (M is a natural number) marks 10. In this case, a first mark 10 is formed on a first layer, and an M-th mark 10 is formed on an M-th layer. In the shot 30B, the first to third marks 10 are arranged in the semiconductor chip 1B as one mark group 15B.

As described above, in the shot 30B, the mark group 15B is arranged in the semiconductor chip 1B. Thus, there is no mark group 15B on the scribe line 20B. As a result, when the scribe line 20B is diced, it is possible to suppress the occurrence of dust or chipping.

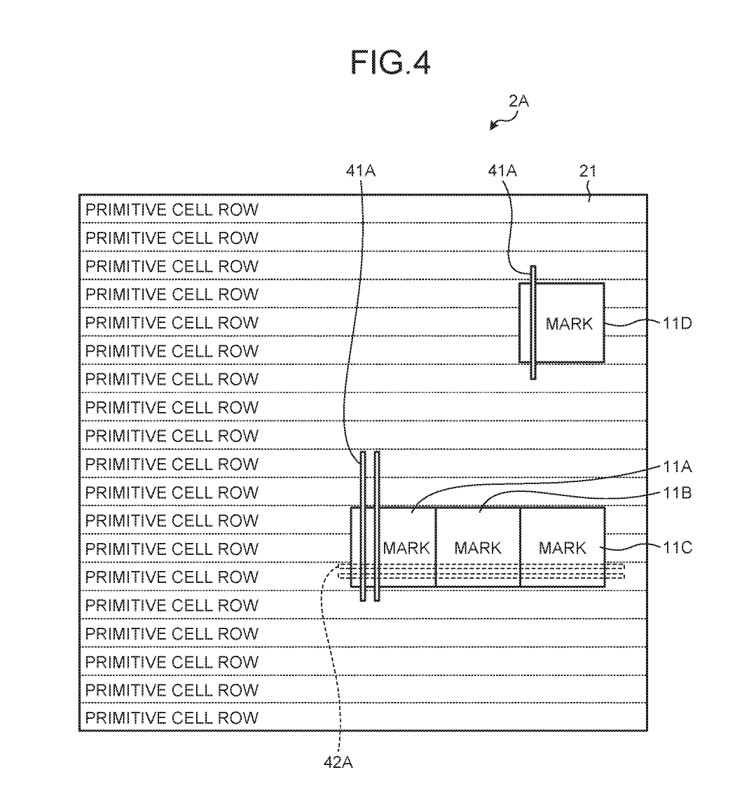

FIG. 4 is a diagram illustrating an arrangement example of a mark and an interconnection of an underlying group. The primitive cell region 2A is an example of the primitive cell region 2. Here, a pattern arrangement setting (pattern data generation) in the primitive cell region 2A will be described.

Marks 11A to 11D serving as second marks which are the same marks as the mark 10 serving as the first mark are arranged in the primitive cell region 2A. The marks 11A to 11D are arranged in a region of the primitive cell region 2A in which the primitive cell row 21 is not arranged.

Further, the upper layer side pattern is arranged at a side of a layer above the marks 11A to 11D. Here, the marks 11A to 11D are, for example, marks formed on a layer of the underlying group. The layer of the underlying group is a layer formed by a process before a process of forming a contact hole. For example, the layer of the underlying group is formed by an implantation process or the like.

The upper layer side pattern is a pattern formed by a process after a process of forming the marks 11A to 11D. Here, the description will proceed with an example in which the upper layer side pattern includes interconnections (interconnection patterns) 41A and 42A. The interconnections 41A and 42A are patterns for connecting certain patterns in the semiconductor chip 1X. The interconnections 41A and 42A are, for example, line-like patterns having conductivity. The interconnections 41A and 42A may be dummy patterns (dummy interconnections).

As described above, in the semiconductor chip 1X, the marks 11A to 11D may be arranged in the semiconductor chip 1X, and the interconnections 41A and 42A may be formed above the marks 11A to 11D.

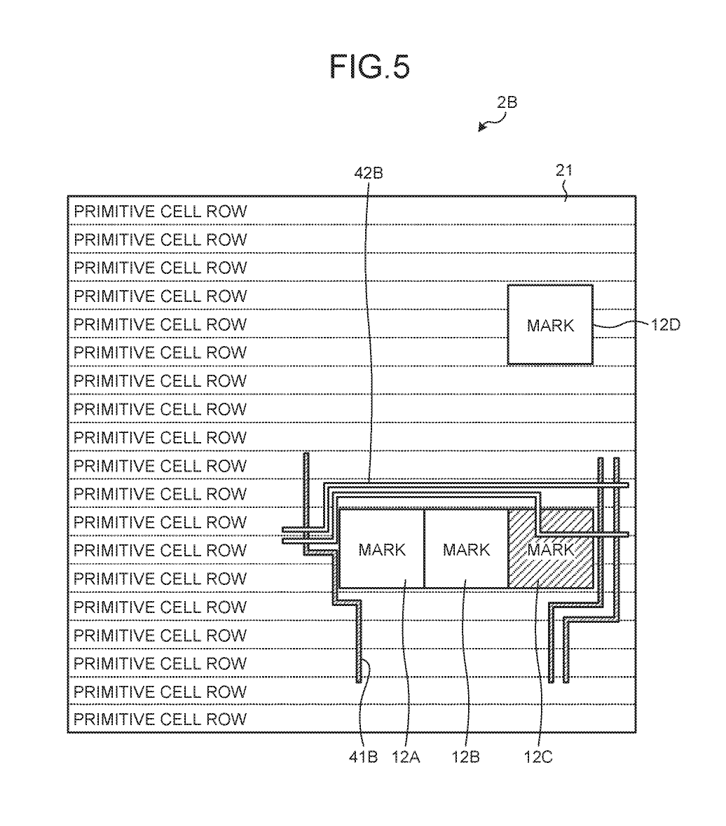

FIG. 5 is a diagram illustrating an arrangement example of a mark and an interconnection of an overlaying group. A layer of the overlaying group is a layer formed by a process after a process of forming a contact hole.

The primitive cell region 2B is an example of the primitive cell region 2. Here, the pattern arrangement setting (pattern data generation) in the primitive cell region 2B will be described.

Marks 12A to 12D which are the same mark as the mark 10 are arranged in the primitive cell region 2B. The marks 12A to 12D are arranged, for example, in a region of the primitive cell region 2B in which the primitive cell row 21 is not arranged.

Here, the marks 12A to 12C are, for example, marks formed on the layer of the overlaying group. The layer of the overlaying group is a layer formed by an interconnection process or the like. In addition, the upper layer side pattern is arranged on a side of a layer above the mark 12C. The upper layer side pattern is a pattern formed by a process after a process of forming the mark 12C.

The mark 12C is a pattern formed by a first interconnection process, and the marks 12A and 12B are patterns formed by a second interconnection process of a layer above the mark 12C. An interconnection 41B is a pattern formed by the first interconnection process, and an interconnection 42B is a pattern formed by the second interconnection process. The interconnections 41B and 42B are the same conductive patterns as the interconnections 41A and 42A. Thus, the interconnections 41B and 42B may be a dummy pattern (dummy interconnection).

The interconnection 41B is a pattern formed by the first interconnection process and thus arranged not to overlap the mark 12C formed by the first interconnection process. In other words, the mark 12C is arranged not to overlap the interconnection 41B on the same layer as the mark 12C.

The interconnection 42B is a pattern formed by the second interconnection process and thus arranged not to overlap the marks 12A and 12B formed by the second interconnection process. In other words, the marks 12A and 12B are arranged not to overlap the interconnection 42B on the same layer as the marks 12A and 12B.

The interconnection 41B is a pattern formed by the first interconnection process and thus arranged riot to overlap the marks 12A and 12B formed by the second interconnection process. In other words, the marks 12A and 12B are arranged not to overlap the interconnection 41B on the layer lower than the marks 12A and 12B.

Meanwhile, the interconnection 42B is a pattern formed by the second interconnection process and thus may be arranged to overlap the mark 12C formed by the first interconnection process. In other words, the mark 12C may be arranged to overlap the interconnection 42B on the layer higher than the mark 12C. FIG. 5 illustrates an example in which the interconnection 42B is formed to overlap a portion above the mark 12C.

Here, a process of arranging the marks 12A to 12C and the interconnections 41B and 42B will be described. After a setting to arrange the marks 12A to 12C is performed, the region in which the mark 12C is arranged is set as an arrangement prohibition region of the interconnection 41B. Then, the interconnection 41B is arranged so that the interconnection 41B does not come into contact with the arrangement prohibition region of the interconnection 41B. Thus, the interconnection 41B is arranged to bypass the mark 12C.

Further, after the setting to arrange the marks 12A to 12C is performed, the region in which the marks 12A and 12B are arranged is set as the arrangement prohibition region of the interconnection 42B. Then, the interconnection 42B is arranged so that the interconnection 42B does not come into contact with the arrangement prohibition region of the interconnection 425. Thus, the interconnection 42B is arranged to bypass the marks 12A and 12B.

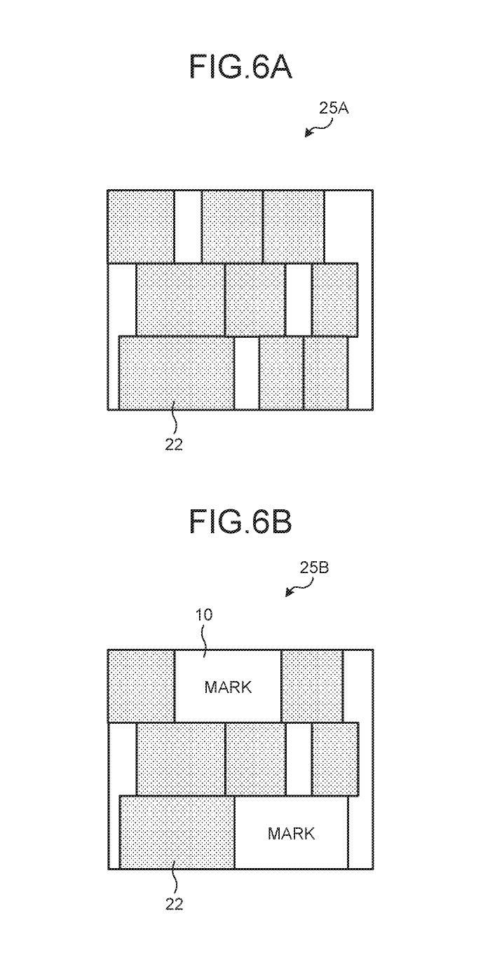

The mark 10 may be arranged after the primitive cell rows 21 are arranged or may be arranged before the primitive cell rows 21 are arranged. FIG. 6 is a diagram for describing a process or arranging the mark after the primitive cells are arranged. In FIGS. 6A and 6B, a part of the primitive cell region 2 is illustrated. Here, an arrangement setting (pattern data generation) of the mark 10 will be described. A primitive cell 22 illustrated in FIGS. 6A and 6B is a part of the primitive cell row 21.

FIGS. 6A illustrate a state (a mark non-arranged state 25A) in which the primitive cell 22 is arranged, but the mark 10 is not arranged yet. FIG. 6B illustrate a state (a mark arranged state 25B) in which the primitive cell 22 is arranged, and then the mark 10 is arranged as well.

When the primitive cell 22 is arranged, a gap occurs between the primitive, cells 22 as illustrated in FIG. 6A. For example, when the aspect ratio of the primitive cell region 2 is low, the primitive cell region 2 has a shape close to a square. In this case, since the primitive cell 22 can be flexibly arranged in both the vertical direction and the traverse direction, the primitive cell 22 is easily arranged. As a result, the cell density can be increased. However, when the cell density is increased, a gap in which the mark 10 is arranged is decreased.

As described above, when the gap is small, the arranged primitive cells 22 are moved. Specifically, the primitive cells 22 are moved, for example, using a design violation part restoration tool with which the automatic P&R device is equipped. The design violation part restoration tool is a tool for moving the primitive cells 22 so that design violation does not occur. After the mark 10 or the mark region is arranged, for example, when a design rule violation in which the primitive cell 22 and the mark 10 (the mark region) which are already arranged overlap occurs, the design violation part restoration tool moves the primitive cells 22. When it is hard to solve all design violations, an arrangement condition (for example, arrangement positions) of the primitive cells 22 may be changed. In this case, the automatic P&R device may move the primitive cells 22 again, or the primitive cells 22 may be manually moved. Through the movement of the primitive cells 22, the gap in which the mark 10 can be arranged is secured. Thereafter, the mark 10 is arranged in the gap between the primitive cells 22 as illustrated in FIG. 6B.

On the other hand, when the aspect ratio of the primitive cell region 2 is high, it is hard to flexibly arrange the primitive cells 22 in any of the vertical direction and, the traverse direction, and thus it is difficult to arrange the primitive cells 22. As a result, it is difficult to increase the cell density. However, when the cell density is low, the gap in which the mark 10 is arranged is large.

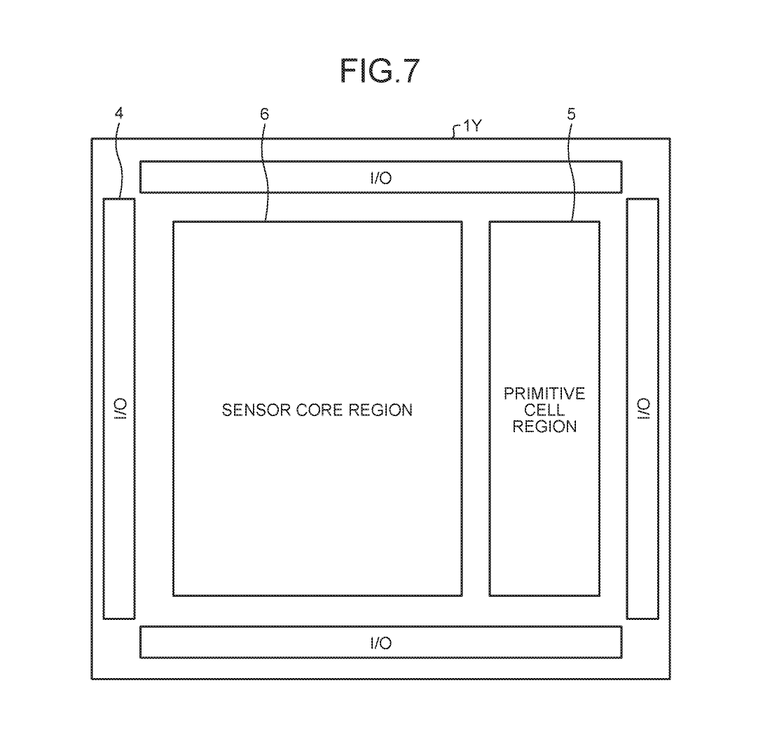

FIG. 7 is a top view schematically illustrating a configuration of a semiconductor chip when the aspect ratio of the primitive cell region is high. A semiconductor chip 1Y is a semiconductor chip similar to the semiconductor chip 1X. The semiconductor chip 1Y is, for example, an image sensor chip. The semiconductor chip 1Y includes a primitive cell region 5 and a sensor core region 6 instead of the primitive cell region 2.

The primitive cell region 5 is a region that is higher in the aspect ratio than the primitive cell region 2. When the semiconductor chip 1Y includes the sensor core region 6 and the like as described above, there are cases in which the aspect ratio of the primitive cell region 5 is high.

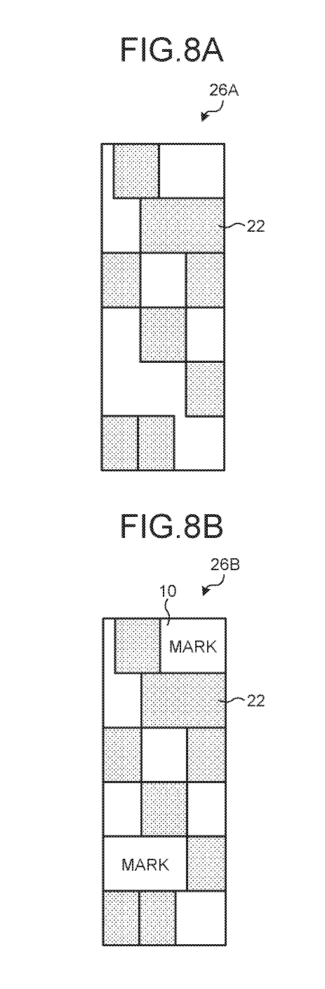

FIGS. 8A and 8B are diagrams for describing a mark arrangement process when the aspect ratio of the primitive cell region is high. In FIGS. 8A and 8B, a part of the primitive cell region 5 is illustrated. Here, an arrangement setting (pattern data generation) of the mark 10 will be described. A primitive cell 22 illustrated in FIGS. 8A and 8B is a part of the primitive cell row 21.

FIG. 8A illustrates a state (a mark non-arranged state 26A) in which the primitive cell 22 is arranged, but the mark 10 is not arranged yet. FIG. 8B illustrate a state (a mark arranged state 26B) in which the primitive cell 22 is arranged, and then the mark 10 is arranged as well.

When the primitive cells 22 are arranged in the primitive cell region 5, a large gap occurs between the primitive cells 22 as illustrated in FIG. 8A. Since the gap sufficient to arrange the mark 10 in the primitive cell region 5 is provided, it is possible to arrange the mark 10 without moving the primitive cells 22 as illustrated in FIG. 8B.

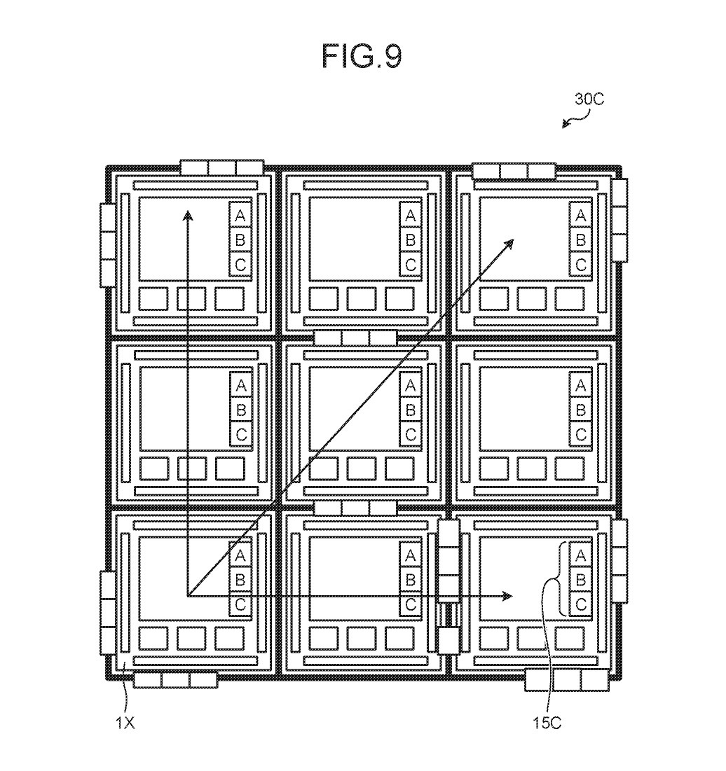

Next, a process of arranging the mark 10 will be described. FIG. 9 is a diagram for describing a first example of the mark arrangement process. Here, the description will proceed with an example in which a setting is performed so that the nine semiconductor chips 1X are arranged in a shot 30C.

When pattern data of the shot 30C is generated, pattern data of the semiconductor chip 1X is generated. At this time, a mark group 15C is arranged in the semiconductor chip 1X. In other words, the pattern data of the semiconductor chip 1X includes pattern data of the mark group 15C.

The mark group 15C is a mark group similar to the mark groups 15A and 15B and includes one or more marks 10. Here, the mark group 15C includes three marks 10. For example, the mark group 15C includes a first mark 10 (A) formed on a first layer, a second mark 10 (B) formed on a second layer, and a third mark 10 (C) formed on a third layer.

After all patterns are completely arranged in the semiconductor chip 1X, the semiconductor chip 1X is arranged in one chip region in the semiconductor chip 1X. The chip region is a rectangular region surrounded by the scribe line. The shot 30C is delimited by a plurality of scribe lines, and one of the delimited regions is one chip region. After the semiconductor chip 1Y is arranged in the chip region, the pattern data of the semiconductor chip 1X is copied. Then, the copied pattern data of the semiconductor chip 1X is pasted to the remaining 8 chip regions.

As a result, the semiconductor chip 1X having the mark group 15C is arranged in the shot 30C. In the shot 30C, the scribe line is arranged in the region in which the semiconductor chip 1X is not arranged.

When the pattern data of the semiconductor chip 1X is copied and pasted, all the semiconductor chips 1X in the shot 30C have the same mark group 15C. Specifically, in all the nine semiconductor chips 1X, the first mark 10 (A), the second mark 10 (B), and the third mark 10 (C) are arranged in the semiconductor chip 1X. Through such an arrangement method, it is possible to easily arrange the mark 10 in the semiconductor chip 1X.

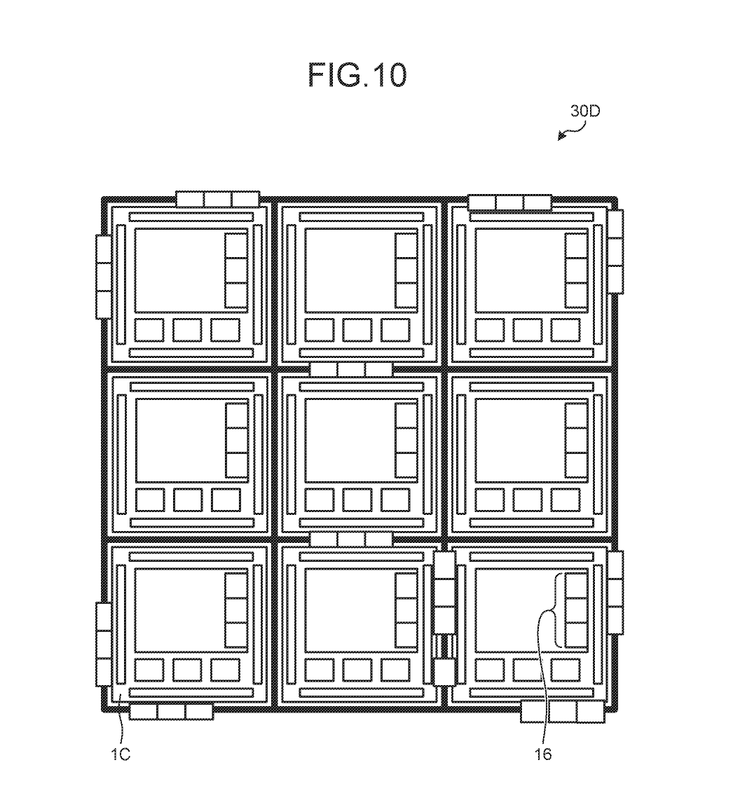

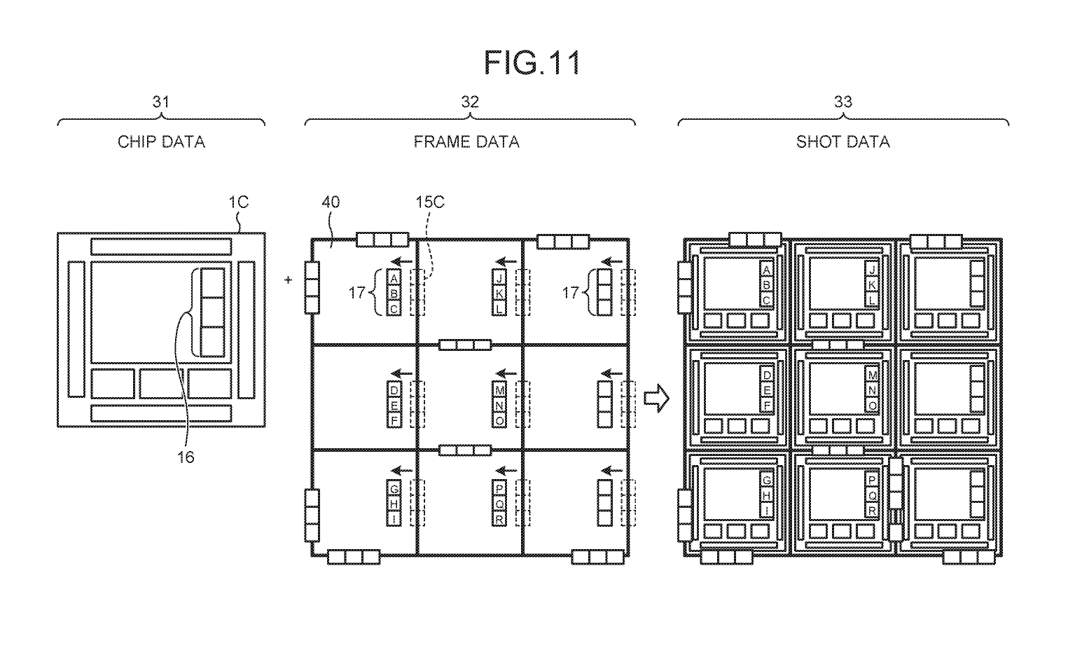

FIG. 10 is a diagram (1) for describing a second example of the mark arrangement process. FIG. 11 is a diagram (2) for describing the second example of the mark arrangement process. A shot 30D illustrated in FIG. 10 is a shot in a state in which a region (a mark region 16) in which the mark 10 is arranged is secured.

When pattern data of the shot 30D is generated, pattern data of the semiconductor chip 1C is generated. At this time, the mark region 16 is arranged in the semiconductor chip 1C. In other words, the pattern data of the semiconductor chip 1C includes pattern data of the mark region 16.

The mark region 16 is a region in which the mark 10 is arranged, and the mark 10 of any layer may be arranged. Each mark region 16 includes property information. The property of the mark region 16 is information used for arranging the mark 10 such as a mark name, a type of the mark 10, and information related to a layer. For example, restriction information (an interconnection prohibition layer and interconnection information) at the time of automatic placing and routing may be added to the property of the mark region 16.

After the pattern data of the shot 30D is generated, pattern data in which various marks 10 are arranged in the mark regions 16 of the shot 30D is generated. As a result, pattern data (shot data 33 which will be described later) in which various marks 10 are arranged in the shot 30D is generated. The snot data 33 is data in which pattern data of the respective layers of the semiconductor device are combined.

As illustrated in FIG. 11, when the shot data 33 is generated, chip data 31 serving as the pattern data of the semiconductor chip 1C is generated. In addition, frame data 32 of the shot 30D is generated. The frame data 32 includes a region (a chip arrangement region 40) in which the semiconductor chip 1C is arranged and a scribe line.

When the frame data 32 is generated, for example, frame data in which the mark group 15C is arranged on the scribe line is generated. In the frame data 32, a mark region 17 is set to the chip arrangement region 40.

The chip arrangement region 40 and the chip data 31 of the semiconductor chip 1C have the same size and the same shape. The mark region 16 of the semiconductor chip 1C and the mark region 17 of the chip arrangement region 40 have the same size and the same shape. The position of the mark region 16 in the semiconductor chip 1C is the same as the position of the mark region 17 in the chip arrangement region 40.

In the frame data 32, the mark group 15C on the scribe line is moved in the chip arrangement region 40. At this time, the mark group 15C is moved to the mark region 17.

By copying and pasting the chip data 31, the pattern data of the shot 30D illustrated in FIG. 10 is generated. Then, by combining the pattern data (the chip data 31) and the frame data 32 of the shot 30D, the shot data 33 is generated. As a result, the mark group 15C arranged on the scribe line of the frame data 32 is arranged in the region other than the scribe, line.

The mark 10 of any layer may be arranged in the mark regions 16 and 17. Thus, the different mark groups 15C (the different marks 10) may be arranged in the mark regions 16 of the respective semiconductor chips 1C. For example, a first mark group 15C (A, B, and C) may be arranged in a first mark region 16 of a first semiconductor chip 10, and a second mark group 15C (D, E, and F) may be arranged in a second mark region 16 of a second semiconductor chip 1C.

The mark 10 may be arranged, for example, on each layer of a wafer process. For example, when a first layer is aligned, with a second layer, and a second layer is aligned with a third layer, the marks 10 of the first to third layers are arranged on the shot data 33.

The mark 10 of the first layer serves as a mark (a first mark) for alignment with the second layer. The mark 10 of the second layer serves as a mark (a second mark) for alignment with the first layer and a mark (a third mark) for alignment with the third layer. The mark 10 of the third layer serves as a mark (a fourth mark) for alignment with the second layer. Further, when the semiconductor chip 1X is manufactured, the second mark is aligned with the first mark, and the fourth mark is aligned with the third mark.

After the shot data 33 is generated, the pattern data of the shot data 33 is divided for each layer, and pattern data of each layer is generated. After the pattern data of each layer is generated, a mask is manufactured for each layer. The mask may be a photomask or may be a mask (for example, an imprint template) other than a photomask. For example, after a photomask is manufactured, the semiconductor chip 1X (semiconductor integrated circuit) is manufactured on a substrate such as a wafer.

Specifically, a processed film is formed on a wafer. Then, the processed film is coated with a resist. Thereafter, the wafer coated with the resist is subject to light exposure using the photomask. At this time, a lower layer side pattern is aligned with an upper layer side pattern using the mark 10 described in the present embodiment. In this state, the resist is exposed to light, then the wafer is developed, and a resist pattern is formed on the wafer. Then, the processed film is etched using the resist pattern as a mask. As a result, a real pattern corresponding to the resist pattern is formed on the wafer. When the semiconductor chip 1X is manufactured, a forming process, an exposure process, a development process, an etching process, and the like of the processed film are repeated for each layer.

The wafer on which the semiconductor chip 1X is formed is diced along the scribe line. In the present embodiment, the mark 10 is arranged in the semiconductor chip 1X, and the upper layer side pattern such as the interconnection pattern is arranged above the mark 10, and thus an increase in a shot size can be suppressed. In addition, an increase in a chip size of the semiconductor chip 1X can be suppressed. Furthermore, since the number of marks 10 arranged on the scribe line can be reduced, it is possible to reduce dust and chipping at the time of dicing.

Further, when the semiconductor chip 1Y is an image sensor chip, the cell density of the primitive cell region 5 may be decreased, but since the mark 10 can be arranged in the cell space, the increase in the chip size can be suppressed.

As described above, according to the embodiment, the mark 10 serving as the inspection pattern is arranged in the chip region of the semiconductor chip 1X. In addition, the interconnections 41A, 42A, and 42B serving as the upper layer side pattern are arranged to overlap the mark 10 at the side of the layer higher than the mark 10. Accordingly, the increase in the chip area size can be suppressed.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device, comprising:
a first inspection pattern that is arranged in a chip region of a semiconductor chip; and
an upper layer side pattern that is arranged on a side of a layer higher than the first inspection pattern and overlaps at least a part of the first inspection pattern.

2. The semiconductor device according to claim 1, further comprising,
a second inspection pattern that is arranged on the same layer as the upper layer side pattern,
wherein the second inspection pattern is arranged in the chip region, and the second inspection pattern is arranged not to overlap a pattern at a side of a layer lower than the second inspection pattern.

3. The semiconductor device according to claim 1,
wherein the first inspection pattern is arranged not to overlap a pattern at a side of a layer lower than the first inspection pattern.

4. The semiconductor device according to claim 1,
wherein the upper layer side pattern is an interconnection pattern.

5. The semiconductor device according to claim 2, further comprising,
a lower layer side pattern that is arranged on the same layer as the first inspection pattern,
wherein the lower layer side pattern is arranged in the chip region, and the second inspection pattern is arranged not to overlap the lower layer side pattern.

6. The semiconductor device according to claim 5,
wherein the lower layer side pattern is an interconnection pattern.

7. An inspection pattern arrangement method, comprising:
generating pattern data of a first inspection pattern arranged in a chip region of a semiconductor chip; and
generating pattern data of an upper layer side pattern that is arranged on a side of a layer higher than the first inspection pattern and overlaps at least a part of the first inspection pattern.

8. The inspection pattern arrangement method according to claim 7, further comprising,
generating pattern data of a second inspection pattern that is arranged on the same layer as the upper layer side pattern,
wherein the second inspection pattern is arranged in the chip region, and the second inspection pattern is arranged not to overlap a pattern at a side of a layer lower than the second inspection pattern.

9. The inspection pattern arrangement method according to claim 7,
wherein the first inspection pattern is arranged not to overlap a pattern at a side of a layer lower than the first inspection pattern.

10. The inspection pattern arrangement method according to claim 7,
wherein the upper layer side pattern is an interconnection pattern.

11. The inspection pattern arrangement method according to claim 8, further comprising,
generating pattern data of a lower layer side pattern that is arranged on the same layer as the first inspection pattern,
wherein the lower layer side pattern is arranged in the chip region, and the second inspection pattern is arranged not to overlap the lower layer side pattern.

12. The inspection pattern arrangement method according to claim 11,
wherein the lower layer side pattern is an interconnection pattern.

13. The inspection pattern arrangement method according to claim 7,
wherein the first inspection pattern is arranged on a side of a layer higher than a pattern having no remaining shape.

14. The inspection pattern arrangement method according to claim 7,
wherein the first inspection pattern is arranged in a region in which no primitive cell is arranged in a primitive cell region.

15. A method of manufacturing a semiconductor device, comprising:
generating first pattern data of a first inspection pattern arranged in a chip region of a semiconductor chip;
generating second pattern data of an upper layer side pattern that is arranged on a side of a layer higher than the first inspection pattern and overlaps at least a part of the first inspection pattern;
forming the first inspection pattern using the first pattern data; and
forming the upper layer side pattern using the second pattern data

16. The method of manufacturing the semiconductor device according to claim 15, further comprising,
generating third pattern data of a second inspection pattern that is arranged on the same layer as the upper layer side pattern,
wherein the second inspection pattern is arranged in the chip region, and the second inspection pattern is arranged not to overlap a pattern at a side of a layer lower than the second inspection pattern.

17. The method of manufacturing the semiconductor device according to claim 15,
wherein the first inspection pattern is arranged not to overlap a pattern at a side of a layer lower than the first inspection pattern.

18. The method of manufacturing the semiconductor device according to claim 15,
wherein the upper layer side pattern is an interconnection pattern.

19. The method of manufacturing the semiconductor device according to claim 16, further comprising,
generating fourth pattern data of a lower layer side pattern that is arranged on the same layer as the first inspection pattern,
wherein the lower layer side pattern is arranged in the chip region, and the second inspection pattern is arranged not to overlap the lower layer side pattern.

20. The method of manufacturing the semiconductor device according to claim 19,
wherein the lower layer side pattern is an interconnection pattern.
